(19) United States
(12) Patent Application Publication
(10) Pub. No.: US 2010/0006973 A1
(43) Pub. Date: Jan. 14, 2010

(54) STI Structure At SOI/Bulk Transition For HOT Device

(75) Inventor: Yusuke KOHYAMA, Yokohama (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: KABUSHIKI KAISHA TOSHIBA, Tokyo (JP)

(21) Appl. No.: 12/402,499

(22) Filed: Mar. 12, 2009

Related U.S. Application Data
(60) Provisional application No. 61/037,308, filed on Mar. 17, 2008.

(51) Int. Cl. H01L 29/06; H01L 21/762

(52) U.S. Cl. 257/506; 438/425; 257/E29.02; 257/E21.545

(57) ABSTRACT

A semiconductor device with STIs separating HOT regions is described. Processes for eliminating voids due to misalignments in boundary region STIs are described.

### RELATED APPLICATION

This application claims priority to U.S. Provisional Application Ser. No. 61/037,308, filed Mar. 17, 2008, whose contents are expressly incorporated herein by reference.

### TECHNICAL FIELD

Aspects of the invention relate to semiconductors.

### BACKGROUND

Silicon-on-insulator (SOI) technology has provided a number of benefits to the advancement of semiconductor devices and device processing. One advantage is the use of hybrid orientation technology (HOT) that provides a structure by which different silicon crystal orientations may be used in a single chip. As an example, a silicon substrate may have a crystalline orientation of (100) and a second silicon region may have a crystalline orientation of (110). The second silicon region may be disposed on top of a buried oxide layer (BOX) surrounded by shallow trench isolation regions (STI). By placing a seed crystal in the second silicon region, the silicon in the second region may be grown in accordance with the orientation of the seed crystal. The result is different silicon crystalline orientations for use in the same chip.

The different orientations permit adjustments to particular circuit devices by the selection of the orientation of the substrate as compared to changing the device size. For instance, differences between nFETs and pFETs constructed on a silicon layer having a (100) orientation may be minimized by selectively moving one of these devices to a silicon layer having a (110) orientation, while keeping the same design rules for both devices.

Conventional processing techniques do not address a potential for error in STI regions on the boundary between bulk semiconductor regions and SOI regions.

### SUMMARY

Aspects of the invention pertain to improving STI processing at the boundary between bulk and SOI regions.

### BRIEF DESCRIPTION OF THE DRAWINGS

FIG. 1 shows a transition between a silicon bulk region and a silicon SOI region.

FIGS. 2A-2D shows conventional processing technique for creating STI regions and potential errors.

FIGS. 3A-3B show a processing technique in accordance with aspects of the invention.

FIG. 4 shows the STI regions in accordance with aspects of the invention.

FIG. 5 shows circuits in the SOI and bulk regions of a semiconductor device in accordance with aspects of the invention.

### DETAILED DESCRIPTION

One or more aspects of the invention relate to forming STI regions between different areas of a semiconductor device.

It is noted that various connections are set forth between elements in the following description. It is noted that these connections in general and, unless specified otherwise, may be direct or indirect and that this specification is not intended to be limiting in this respect.

In accordance with one or more aspects, a buried oxide layer is provided on or in a substrate. A different orientation of the bulk material may then be deposited or grown on the buried oxide layer. Circuits may then be formed in the semiconductor with the first orientation and in the semiconductor with the second orientation.

Various applications of SOI/Bulk hybrid substrates have been proposed. One application is for embedded DRAMs such as suggested in an article by R. Hannon, et al., Symp. on VLSI Tech. Dig., p. 66, 2000 and another article by T. Yamada, et al., Symp. on VLSI Tech. Dig., p. 112, 2002. Both papers show SOI/Bulk hybrid wafers which have embedded DRAMs in the bulk area and logic devices in the SOI area. Another application is for a high performance CMOS logic using HOT (hybrid orientation technology) described in an article by M. Yang, et al., IEDM Tech. Dig., p. 453, 2003. HOT may also use the SOI/Bulk hybrid wafer which has an nFET on the SOI region, where the silicon in the SOI region has a [100] crystal orientation, and PFET on the bulk region with a [110] crystal orientation.

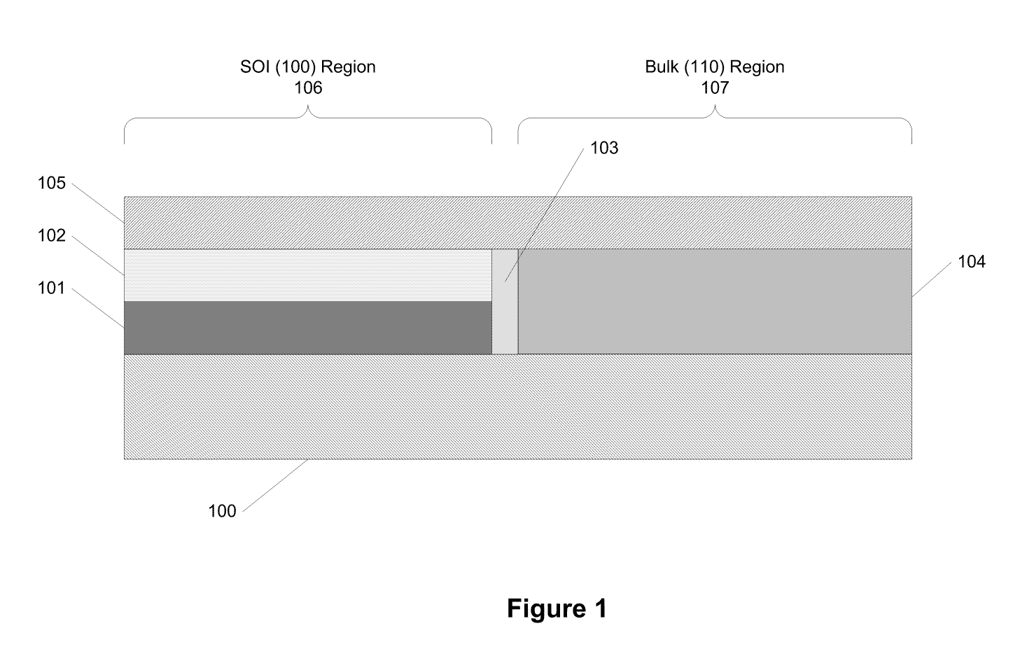

An illustrative cross section of a HOT wafer is shown in FIG. 1. The fabrication process for the HOT device may be as follows. First, a bulk substrate of a first orientation (for instance, a [110] orientation is provided. Next, an oxide 101 is grown on bulk substrate 100. Next, a silicon layer (here the SOI layer) 102 is deposited on the oxide 101. At this point, because oxide 101 is buried, it is referred to as a BOX (buried oxide) 101. The wafer includes the SOI layer 102 having a [100] crystal orientation, the BOX (buried oxide) 101, and the substrate 100 having the [110] crystal orientation.

Next, a mask layer (not shown) was formed on SOI surface. The mask layer, the SOI, and BOX are patterned using conventional lithography and RIE (reactive ion etching) techniques.

Next, sidewall spacer 103 is formed at an exposed sidewall. Epitaxial layer 104 is then grown on an exposed substrate surface of substrate 100. Here, because the epitaxial layer 104 is grown directly on the substrate, it follows the same crystalline orientation as that of substrate 100. Here, the substrate 100 is the seed for the orientation for the growth of the epitaxial layer. Finally, a silicon nitride layer (SiN) 105 is formed on entire surface after removing mask layer.

For ease of explanation, the SOI with its [100] orientation is referred to as SOI (100) Area 106. The bulk area with its [110] orientation is referred to as Bulk (110) Area 107.

Sidewall spacer 103 alone does not provide the isolation needed to isolate circuits in the SOI region 102 from circuits in the epitaxial region 104. Accordingly, a hybrid wafer must have a boundary region between the SOI area 106 and bulk area 107 to effectively isolate the two regions.

Therefore, different three types of isolation elements are needed: an isolation structure for the bulk region 107, an isolation structure or the SOI region 106, and an isolation structure for the boundary between the bulk and SOI regions.

Conventional STI (shallow trench isolation) techniques have been widely used for isolation elements in both the bulk 107 and SOI regions 106. However, standard STI processing creates a problem in the boundary region.

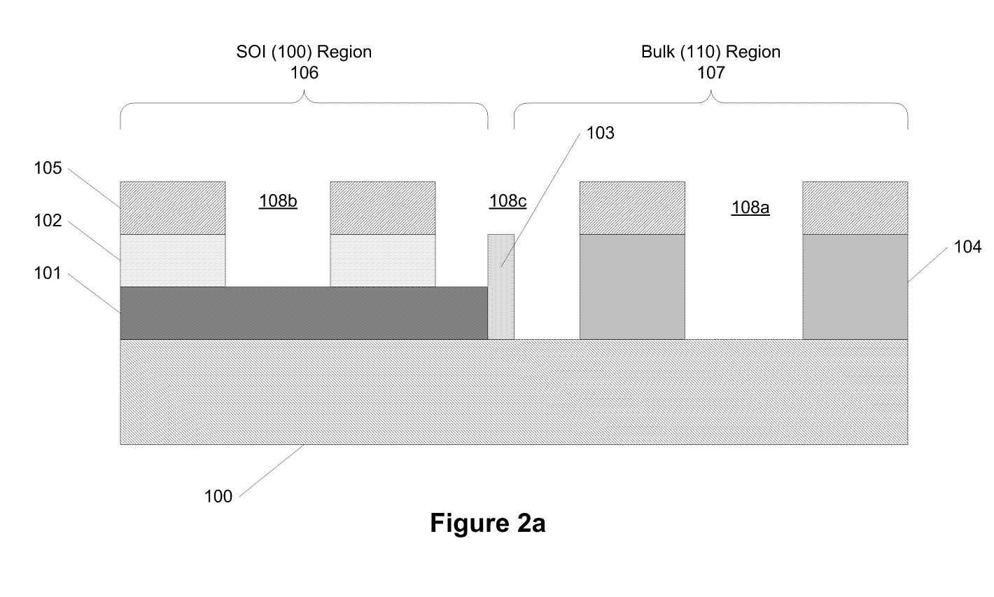

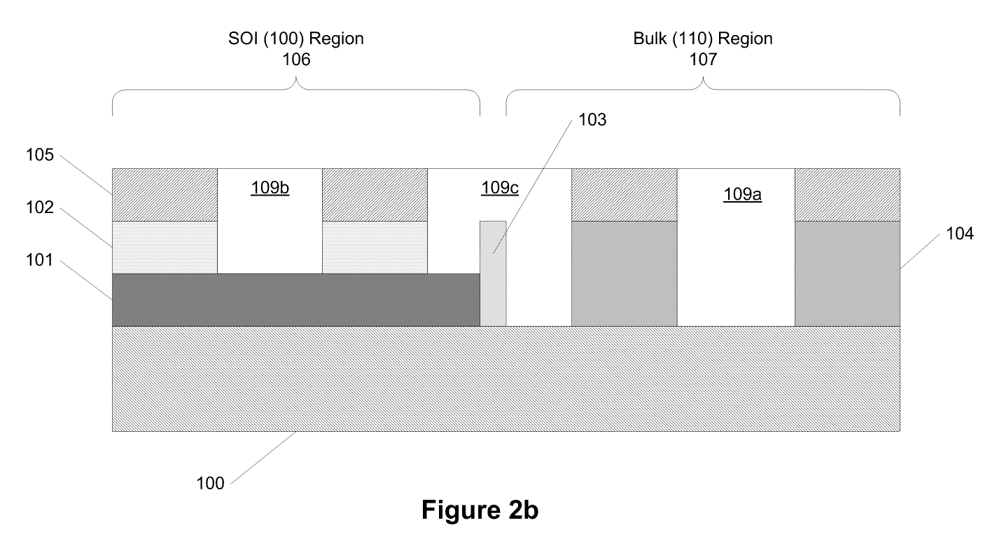

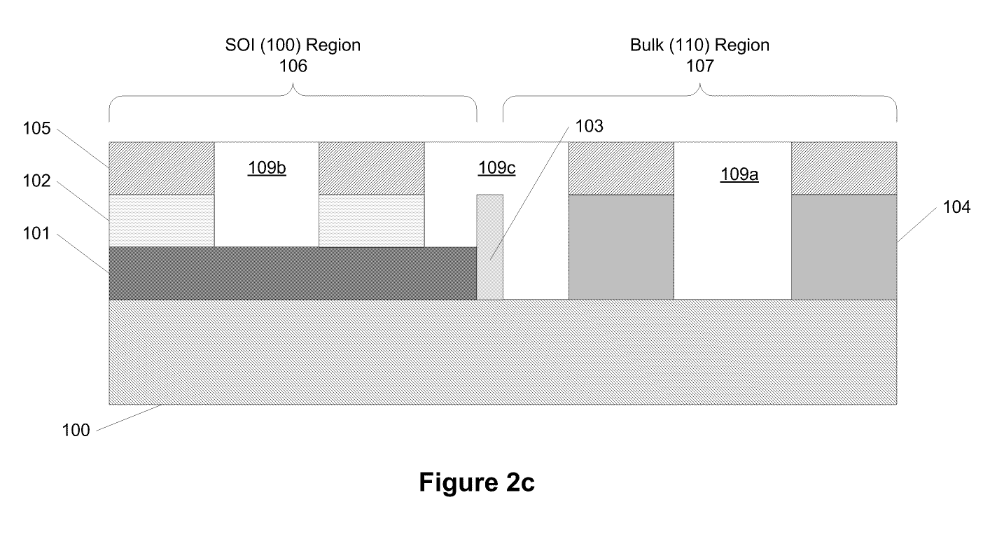

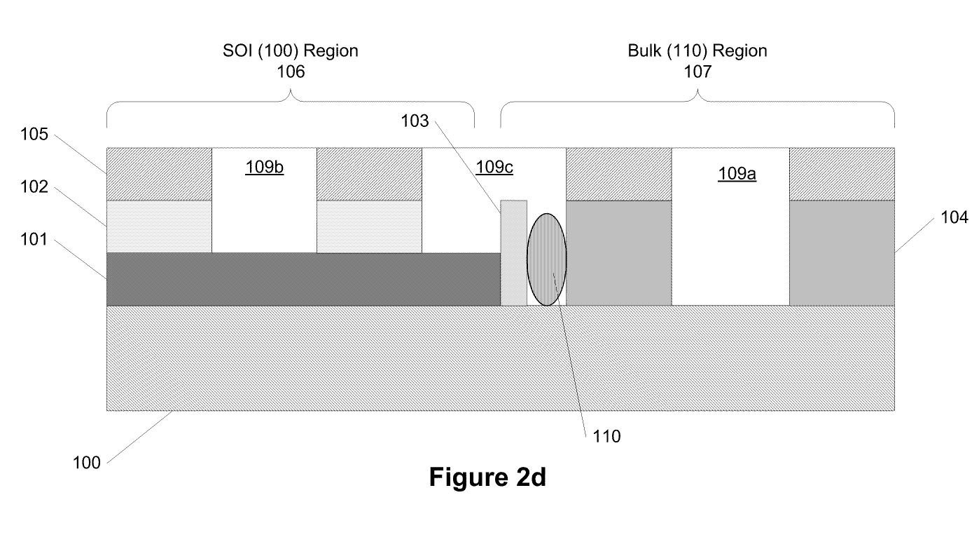

A conventional STI process in HOT is shown in FIGS. 2A-2D. In the transition from FIG. 1 to FIG. 2A, the SiN layer 105 was patterned using conventional lithography and RIE techniques. A silicon RIE that is selective (selective to not etch) to the oxide and SiN was then applied.

The result is a relatively deep trench 108a was formed in bulk area 107 and relatively shallow trench 108b was formed on SOI area 106. The difference in depth is because the silicon oxide layer 101 stops the etching at its surface. Because the silicon oxide layer 101 is higher than the top of substrate 100, the depths of the trenches 108a and 108b differ.

In the boundary area, a shoulder created from the end of the BOX 101 layer and spacer 103 remain in trench 108c as shown in FIG. 2A. In other words, shallower portion and deeper portion were made in one trench at the same time. In FIG. 2B, an oxide fills trenches 108a-108c. The oxide is then planarized using conventional chemical-mechanical polishing (CMP) techniques.

The result is FIG. 2C in which three different isolation elements are present: STI 109a in the bulk region 107, STI 109b in the SOI region 106, and STI 109c in the boundary between the bulk region 107 and the SOI region 106.

FIG. 2C shows an ideal model of the filling of trench 108c forming STI 109c. However, patterned STI always has some misalignment against the boundary between the bulk region 107 and the SOI region 106. FIG. 2D shows the standard misalignment situation. In FIG. 2D, the sidewall spacer 103 is off-center in a trench formed over the boundary between the bulk region 107 and the SOI region. 106. Because of the off-center alignment, the deeper portion (on the bulk region 107 side) is narrower than desired. When filled with the insulator to form STI 109c, the insulator does not completely fill the trench, thereby creating a void 110. The void 110 prevents the desired level of isolation from being achieved between the bulk region 107 and the SIO region 106.

It is appreciated that the formation of the voids 110 at the boundary between the bulk region 107 and the SOI region 106 depends on the width of the STI region 109c itself. If the STI region 109c is narrow, the chance for the occurrence of a void 110 increases. If the STI region 109c is wide, the chance for the occurrence of the void 110 decreases. As dimensions for circuits decrease, the result is a desire to make STI regions as narrow as effectively possible while still providing adequate isolation between regions.

For instance, a larger dimension STI may be allowable in embedded DRAM applications. In these embedded DRAM applications (eDRAM applications), the STI 109c at the boundary is used to separate DRAM arrays from logic circuits. The impact of the size of the STI 109c on the chip size can be suppressed because each area (the DRAM arrays and the logic circuits) is relatively large. On the other hand, small dimension are required in the HOT applications. In the HOT case, the STI at the boundary is needed to separate nFETs from pFETs. In short, in the HOT environment, the STI is separating individual devices, not between large arrays of memory or logic circuits. Because of the number of separate STI boundary occurrences, the nFET/pFET isolation has a large impact on the chip size because of the size of the minimum dimensions for the nFET/pFET isolation and the large number of nFET/pFET isolations occurring on a chip. Accordingly, misalignment is a severe issue in HOT applications.

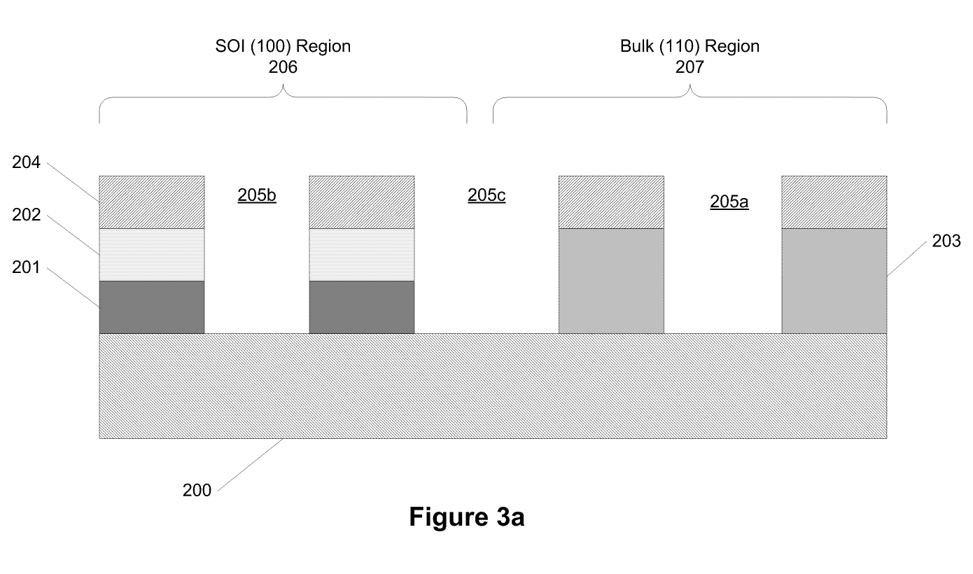

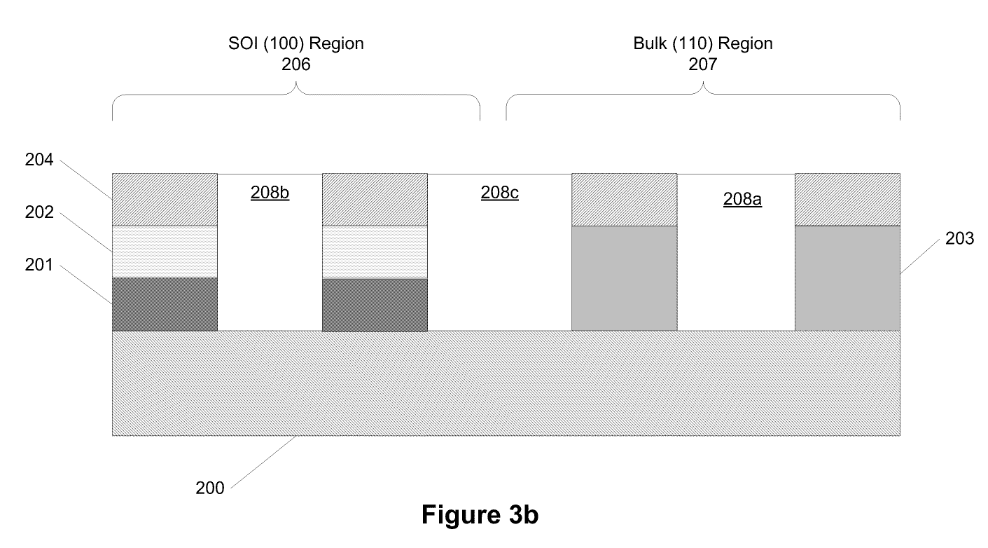

FIGS. 3A-3B show various aspects of the present invention. FIG. 3A shows a cross-sectional view with bulk substrate 200, BOX layer 201, SOI layer 202, epitaxial layer 203 and silicon nitride layer 205. From FIG. 1, the silicon nitride layer 105 was patterned. Next, instead of a selective silicon RIE etch, a non-selective RIE etch (non-selective to the oxide) was used. The result is shown in FIG. 3A. Here, the SOI layer 202, the BOX layer 201, the spacer 103 (from FIG. 1), epitaxial layer 203, and substrate 100 were etched at the same etch rate. Similar shaped trench 205a, 205b, and 205c were formed in the bulk region 207, the SOI region 206, and in the boundary between the two regions 207 and 206.

Next, in FIG. 3B, an oxide is filled into the trenches and planarized by CMP, thereby forming STI regions 208a, 208b, and 208c. The formation process of FIGS. 3A and 3B eliminate the void 113 by eliminating the filling of trench 205c surrounding the sidewall spacer 103 and possibly failing to completely fill trench 205c. Accordingly, despite any misalignment, the formation of void 113 is eliminated by preventing the interference of sidewall space 103 with the filling process of trench 208c.

The STI of 208c may be described as contacting the vertical portion of BOX layer 201, the horizontal portion of substrate 200 and the vertical portion of epitaxial layer 203.

In contrast to FIGS. 2C and 2D, the STI in the boundary region did not contact the vertical end of the BOX layer. Rather, the STI 109c only contacted the horizontal portion of BOX 101. The STI 109c contacted the vertical portions of sidewall spacer 103.

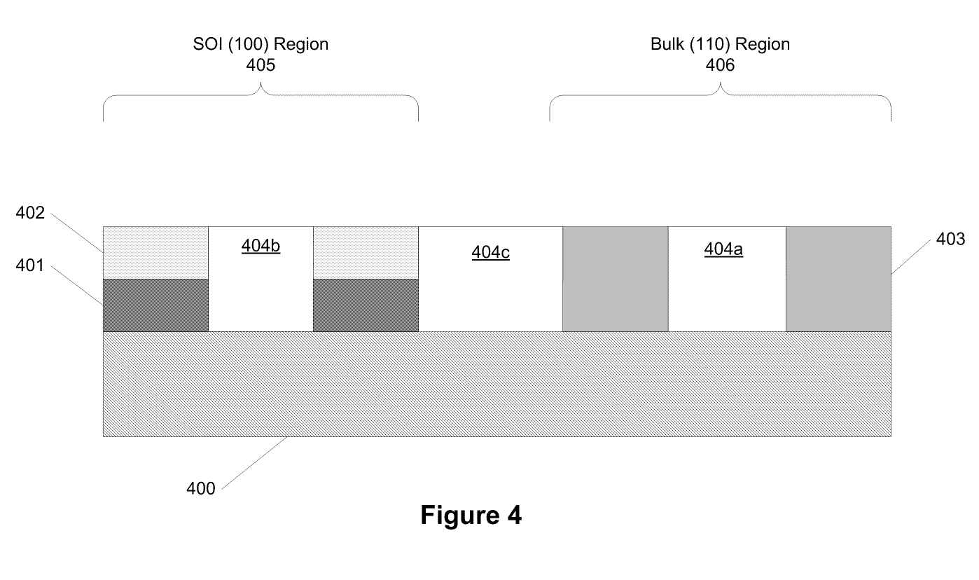

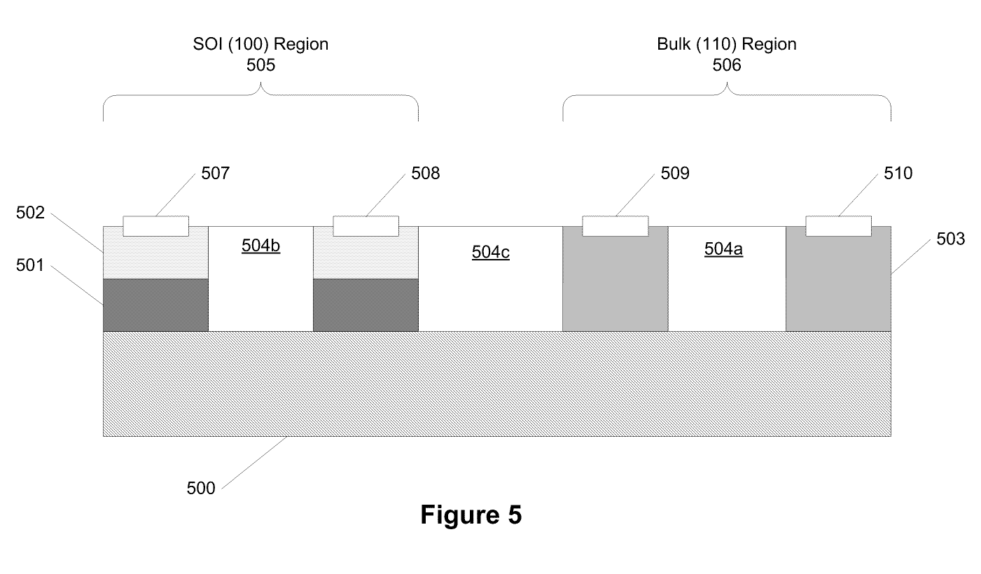

FIGS. 4 and 5 show additional finishing steps. FIG. 4 shows substrate 400, BOX layer 401, SOI layer 402, epitaxial layer 403, and STI regions 404a, 404b, and 404c in the bulk region 406, the SOI region 405, and in the boundary between the bulk region 406 the SOI region 405, respectively. Here, the silicon nitride layer 204 of FIG. 3B has been removed by standard processes.

FIG. 5 shows completed elements in the bulk region 506 and in the SOI region 505. Here, FIG. 5 shows substrate 500, BOX layer 501, SOI layer 502, epitaxial layer 503, and STI regions 504a, 504b, and 504c in the bulk region 506, the SOI region 405, and in the boundary between the bulk region 506 the SOI region 505, respectively. Elements 507 and 508 are formed on the SOI layer 502 and separated from each other by the STI 504b. Elements 509 and 510 are formed on the epitaxial layer 503 and separated from each other by STI 504a. Elements 508 and 509 are separated by the STI 504c on the border between the bulk region 506 and the SOI region 505.

It is appreciated that the BOX layer may be formed by etching into substrate as compared to layering the BOX layer on top of the substrate. In this alternative example, the epitaxial layer may not be deposited, but rather the STI regions in the bulk region are formed directly in the substrate. This may allow for easier processing by not having to separately deposit the epitaxial layer.

What is claimed is:

1. A semiconductor device comprising:
a substrate having an upper surface;
an SOI region including
a BOX layer;
an SOI layer; and
a first shallow trench isolation in the SOI layer;
an bulk region including
an epitaxial layer;
a second shallow trench isolation in the epitaxial layer; and
a third shallow trench isolation between the SOI region and the bulk region,
wherein the third shallow trench isolation contacts a vertical end of the BOX layer and an upper surface of the substrate.

2. The semiconductor device according to claim 1, wherein the third shallow trench isolation contacts a vertical portion of the epitaxial layer.

3. A process for forming a semiconductor device comprising:
providing a substrate having an upper surface;
forming a BOX layer on the substrate;
depositing a SOI layer on the BOX layer;
forming a sidewall structure at an end of the BOX layer;
forming an epitaxial layer adjacent to the BOX layer and separated from the BOX layer by the sidewall structure;
performing a reactive ion etch using an etchant that is non-selective to the BOX layer and non-selective to the sidewall structure;
filling the trench with an oxide.

4. The process according to claim 3, wherein the reactive ion etch removes a portion of the BOX layer and the sidewall structure.

5. The process according to claim 3, wherein the reactive ion etch results in an exposed vertical side of the BOX layer.

6. The process according to claim 5, wherein the reactive ion etch results in an exposed surface of the substrate from the vertical side of the BOX layer to a vertical side of the epitaxial layer.

7. The process according to claim 6, wherein the filling of the trench results in a void-free shallow trench isolation.
